(19) United States
(12) Patent Application Publication
(10) Pub. No.: US 2025/0015771 A1
(43) Pub. Date: Jan. 9, 2025

(54) ELECTRONIC DEVICES AND ELECTRONIC SYSTEMS

(71) Applicant: SK hynix Inc., Icheon-si Gyeonggi-do (KR)

(72) Inventor: Se Won LEE, Icheon-si Gyeonggi-do (KR)

(73) Assignee: SK hynix Inc., Icheon-si Gyeonggi-do (KR)

(21) Appl. No.: 18/490,557

(22) Filed: Oct. 19, 2023

(30) Foreign Application Priority Data
Jul. 4, 2023 (KR) 10-2023-0086686

(51) Int. Cl. H03F 3/45; H03K 3/356; H03K 19/0185

(52) U.S. Cl. CPC H03F 3/45183; H03K 3/356139; H03K 19/018521

(57) ABSTRACT

An electronic device includes a capacitor connected to an output node of a reception circuit. The reception circuit includes an input unit receiving an input signal and an inverted input signal. The reception circuit also includes a current source including a first PMOS transistor positioned between a power supply voltage terminal and a first internal node and a first NMOS transistor positioned between a ground voltage terminal and a second internal node, the current source configured to amplify a voltage difference of the input signal and the inverted input signal. The reception circuit further includes an output unit driving the output node according to a current supplied from the current source.

### CROSS-REFERENCE TO RELATED APPLICATION

The present application claims priority under 35 U.S.C. 119 (a) to Korean Patent Application No. 10-2023-0086686, filed on Jul. 4, 2023, in the Korean Intellectual Property Office. which is incorporated herein by reference in its entirety.

### BACKGROUND

### 1. Technical Field

Some embodiments of the present disclosure relate to electronic devices and electronic systems that receive input signals having different voltages, sense and amplify a voltage difference between the input signals, and output an amplified signal.

### 2. Related Art

In general, electronic devices receive various signals input from external devices and perform internal operations using the received signals. The electronic devices perform internal operations by adjusting the voltages of the received signals or perform an operation of adjusting the voltages of the received signals and outputting adjusted signals to an external device.

To adjust the voltages of signals, a differential amplification circuit is typically used, and the differential amplification circuit senses and amplifies a difference between input signals having different voltages and outputs amplified input signals.

### SUMMARY

In accordance with an embodiment of the present disclosure is an electronic device including a capacitor connected to an output node of a reception circuit. The reception circuit may include an input unit receiving an input signal and an inverted input signal. The reception circuit may also include a current source including a first PMOS transistor positioned between a power supply voltage terminal and a first internal node and a first NMOS transistor positioned between a ground voltage terminal and a second internal node, the current source configured to amplify a voltage difference of the input signal and the inverted input signal. The reception circuit may further include an output unit driving the output node according to a current supplied from the current source.

Also in accordance with an embodiment of the present disclosure is an electronic device including a transmission circuit configured to output an input signal and an inverted input signal that have different voltages from each other. The electronic device may also include a reception circuit configured to connect a first supply node to a power supply voltage terminal through a first PMOS transistor that is turned on by a first control voltage, and to connect a second supply node to a ground voltage terminal through a first NMOS transistor that is turned on by a second control voltage. The reception circuit may be configured to directly receive a power supply voltage through the first supply node, to directly receive a ground voltage through the second supply node, to control a current input and output between the power supply voltage and ground voltage terminals and internal nodes according to voltages of the input signal and the inverted input signal, and to sense and amplify a voltage difference between the input signal and the inverted input signal to generate an internal clock.

### BRIEF DESCRIPTION OF THE DRAWINGS

FIG. 1 is a block diagram illustrating a configuration of an electronic system according to an embodiment of the present disclosure.

FIG. 2 is a block diagram illustrating a configuration according to an embodiment of an electronic device included in the electronic system shown in FIG. 1.

FIG. 3 is a circuit diagram illustrating a configuration according to an embodiment of a reception circuit included in the electronic device shown in FIG. 2.

FIG. 4 is a circuit diagram illustrating a configuration according to another embodiment of the reception circuit included in the electronic device shown in FIG. 2.

FIGS. 5 and 6 are circuit diagrams illustrating an operation according to an embodiment of the reception circuit shown in FIG. 3.

FIGS. 7 and 8 are circuit diagrams illustrating an operation according to another embodiment of the reception circuit shown in FIG. 4.

FIG. 9 is a diagram illustrating a configuration according to an embodiment of an electronic system to which the electronic system shown in FIG. 1 is applied.

### DETAILED DESCRIPTION OF THE EMBODIMENTS

In the following description of embodiments, when a parameter is referred to as being “predetermined,” it may be intended to mean that a value of the parameter is determined in advance of when the parameter is used in a process or an algorithm. The value of the parameter may be set when the process or the algorithm starts or may be set during a period in which the process or the algorithm is executed.

It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal having a logic “high” level may be distinguished from a signal having a logic “low” level. For example, when a signal having a first voltage correspond to a signal having a logic “high” level, a signal having a second voltage correspond to a signal having a logic “low” level. In an embodiment, the logic “high” level may be set as a voltage level which is higher than a voltage level of the logic “low” level. Meanwhile, logic levels of signals may be set to be different or opposite according to the embodiments. For example, a certain signal having a logic “high” level in one embodiment may be set to have a logic “low” level in another embodiment.

Various embodiments of the present disclosure will be described hereinafter in more detail with reference to the accompanying drawings. However, the embodiments described herein are for illustrative purposes only and are not intended to limit the scope of the present disclosure.

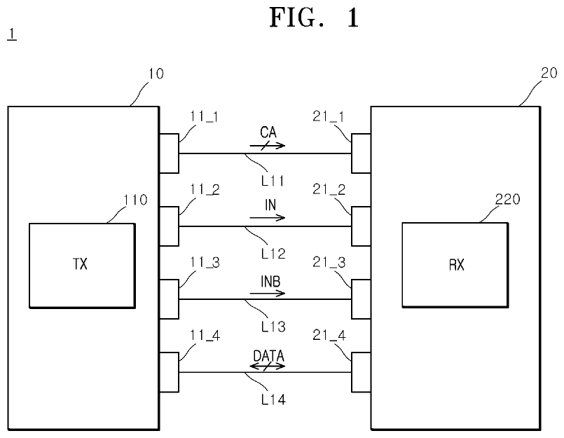

FIG. 1 is a block diagram illustrating a configuration of an electronic system 1 according to an embodiment of the present disclosure. As shown in FIG. 1, the electronic system 1 may include a controller 10 and an electronic device 20. The controller 10 may include a transmission circuit 110. The electronic device 20 may include a reception circuit 220.

The controller 10 may include a first control pin 11_1, a second control pin 11_2, a third control pin 11_3, and a fourth control pin 11_4. The electronic device 20 may include a first device pin 21_1, a second device pin 21_2, a third device pin 21_3, and a fourth device pin 21_4. A first transmission line L11 may be connected between the first control pin 11_1 and the first device pin 21_1. A second transmission line L12 may be connected between the second control pin 11_2 and the second device pin 21_2. A third transmission line L13 may be connected between the third control pin 11_3 and the third device pin 21_3. A fourth transmission line L14 may be connected between the fourth control pin 11_4 and the fourth device pin 21_4.

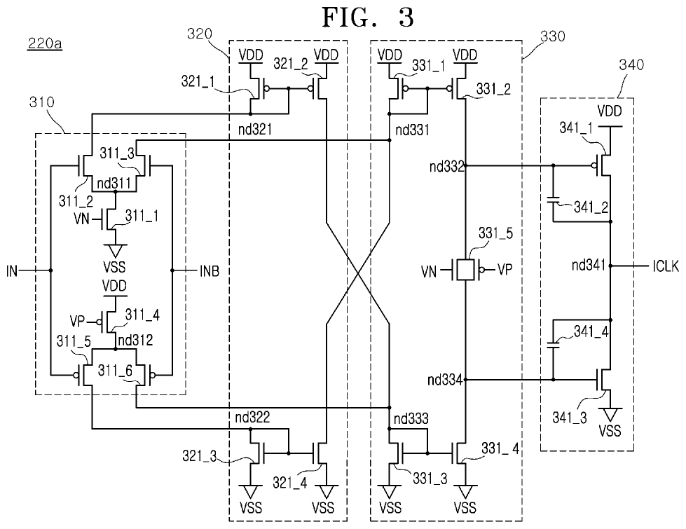

The transmission circuit 110 may output an input signal IN and an inverted input signal INB that have different voltages. The transmission circuit 110 may output the input signal IN and the inverted input signal INB that toggle between a power supply voltage (VDD in FIG. 3) and a ground voltage (VSS in FIG. 3).

The controller 10 may transmit a command address CA for controlling the electronic device 20 to the electronic device 20 through the first transmission line L11. The controller 10 may transmit the input signal IN to the electronic device 20 through the second transmission line L12. The controller 10 may transmit the inverted input signal INB to the electronic device 20 through the third transmission line L13. The controller 10 may transmit data DATA to the electronic device 20 through the fourth transmission line L14. The controller 10 may receive the data DATA from the electronic device 20 through the fourth transmission line L14. The command address CA may include a plurality of bits and may be set as a signal including a command for controlling the operation of the electronic device 20 and an address. The input signal IN and the inverted input signal INB may be set as signals having different voltages. The input signal IN and the inverted input signal INB may be set as signals that toggle between the power supply voltage (VDD in FIG. 3) and the ground voltage (VSS in FIG. 3) according to embodiments. The data DATA may include a plurality of bits, and the plurality of bits may be serially input and output.

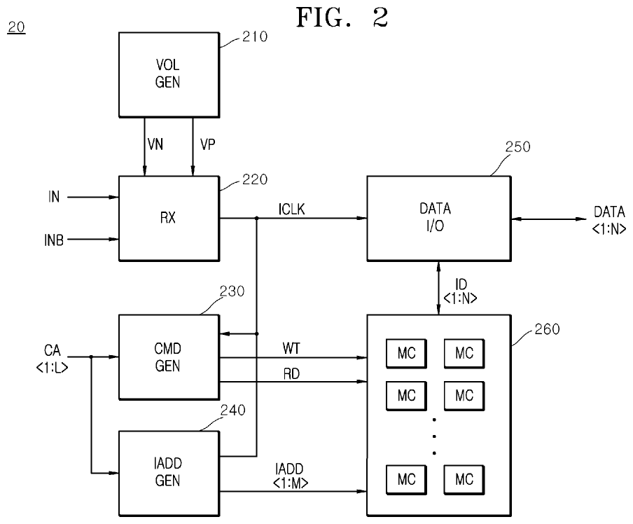

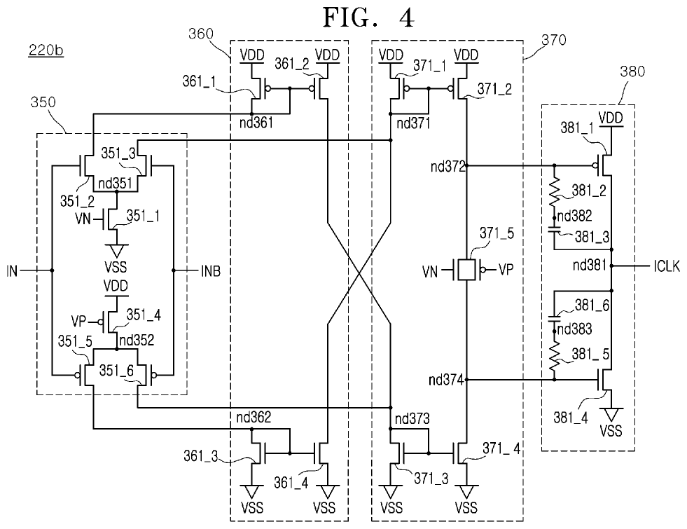

The reception circuit 220 may control the currents input and output between the power supply voltage (VDD in FIG. 3) and ground voltage (VSS in FIG. 3) terminals and internal nodes according to the voltages of the input signal IN and the inverted input signal INB. The reception circuit 220 may sense and amplify a voltage difference between the input signal IN and the inverted input signal INB to generate an internal clock (ICLK in FIG. 2). The reception circuit 220 may connect capacitors (341_2 and 341_4 in FIG. 3, 381_3 and 381_5 in FIG. 4) to an output node (nd341 in FIG. 3) from which the internal clock (ICLK in FIG. 2) is output, and stabilize a frequency of the internal clock (ICLK in FIG. 2) through the capacitors (341_2 and 341_4 in FIG. 3, 381_3 and 381_5 in FIG. 4).

The electronic device 20 may control the currents input and output between the power supply voltage (VDD in FIG. 3) and ground voltage (VSS in FIG. 3) terminals and the internal nodes according to the voltages of the input signal IN and the inverted input signal INB. The electronic device 20 may sense and amplify the voltage difference between the input signal IN and the inverted input signal INB to generate the internal clock (ICLK in FIG. 2). The electronic device 20 may latch the data DATA serially input in synchronization with the internal clock (ICLK in FIG. 2) during a write operation, based on the command address CA. The electronic device 20 may align the latched data DATA to store internal data (ID<1:N> in FIG. 2) generated in parallel during the write operation. The electronic device 20 may serialize the internal data (ID<1:N> in FIG. 2) stored therein in synchronization with the internal clock (ICLK in FIG. 2) during a read operation, based on the command address CA. The electronic device 20 may output the serialized internal data (ID<1:N> in FIG. 2) as the data DATA during the read operation.

FIG. 2 is a block diagram illustrating a configuration according to an embodiment of the electronic device 20 included in the electronic system shown in FIG. 1. As shown in FIG. 2, the electronic device 20 according to an embodiment of the present disclosure may include a voltage generation circuit (VOL GEN) 210, the reception circuit (RX) 220, a command generation circuit (CMD GEN) 230, an internal address generation circuit (IADD GEN) 240, a data input/output circuit (DATA I/O) 250, and a memory circuit 260.

The voltage generation circuit 210 may generate a first control voltage VN for turning on NMOS transistors included in the reception circuit 220. The voltage generation circuit 210 may generate a second control voltage VP for turning on PMOS transistors included in the reception circuit 220. The first control voltage VN may be a voltage input to a gate of each of the NMOS transistors included in the reception circuit 220, and may be generated as a high voltage to turn on the NMOS transistors. The second control voltage VP may be a voltage input to a gate of each of the PMOS transistors included in the reception circuit 220, and may be generated as a low voltage to turn on the PMOS transistors. Here, the high voltage and the low voltage are relative concepts, and the high voltage means a voltage of a first voltage level enough to turn on the NMOS transistor included in the present disclosure and the low voltage means a voltage of a second voltage level enough to turn on the PMOS transistor included in the present disclosure.

The reception circuit 220 may control the current input and output between the power supply voltage (VDD in FIG. 3) terminal and ground voltage (VSS in FIG. 3) terminal and the internal nodes according to the voltages of the input signal IN and the inverted input signal INB. The reception circuit 220 may sense and amplify the voltage difference of the input signal IN and the inverted input signal INB to generate the internal clock (ICLK in FIG. 2). The reception circuit 220 may connect the capacitors (341_2 and 341_4 in FIG. 3, 381_3 and 381_5 in FIG. 4) to the output node (nd341 in FIG. 3) from which the internal clock (ICLK in FIG. 2) is output, and stabilize the frequency of the internal clock (ICLK in FIG. 2) through the capacitors (341_2 and 341_4 in FIG. 3, 381_3 and 381_5 in FIG. 4).

The command generation circuit 230 may generate a write command WT and a read command RD, based on first to “L”^{th} command addresses CA<1:L> in synchronization with the internal clock ICLK. The command generation circuit 230 may generate the write command WT that is enabled when the first to “L”^{th} command addresses CA<1:L> input in synchronization with the internal clock ICLK have a logic level combination for performing a write operation. The command generation circuit 230 may generate the read command RD that is enabled when the first to “L”^{th} command addresses CA<1:L> input in synchronization with the internal clock ICLK have a logic level combination for performing a read operation. The first to “L”^{th} command addresses CA<1:L> may include a command for controlling the write operation and read operation of the electronic device 20 and an address for selecting a memory cell in the write operation and the read operation. The number of bits of the first to “L”^{th} command addresses CA<1:L> may be set to various numbers of bits according to embodiments. The number of bits “L” of the first to “L”^{th} command addresses CA<1:L> may be set as a positive integer.

The internal address generation circuit 240 may generate first to “M”^{th} internal addresses IADD<1:M>, based on the first to “L”^{th} command addresses CA<1:L> in synchronization with the internal clock ICLK. The internal address generation circuit 240 may decode the first to “L”^{th} command addresses CA<1:L> in synchronization with the internal clock ICLK to generate the first to “M”^{th} internal addresses IADD<1:M>. The number of bits of the first to “M”^{th} internal addresses IADD<1:M> may be set to various numbers of bits according to embodiments. The number of bits “M” of the first to “M”^{th} internal addresses IADD<1:M> may be set to a positive integer.

The data input/output circuit 250 may sequentially latch first to “N”^{th} data DATA<1:N> in synchronization with a rising edge and a falling edge of the internal clock ICLK during the write operation. The data input/output circuit 250 may align the first to “N”^{th} data DATA<1:N> latched in synchronization with the rising edge and the falling edge of the internal clock ICLK to generate first to “N”^{th} internal data ID<1:N> during the write operation. The first to “N”^{th} data DATA<1:N> may be input from the controller 10 in the write operation. The data input/output circuit 250 may latch the first to “N”^{th} internal data ID<1:N> in synchronization with the rising edge and the falling edge of the internal clock ICLK during the read operation. The data input/output circuit 250 may serialize the first to “N”^{th} internal data ID<1:N> latched in synchronization with the rising edge and the falling edge of the internal clock ICLK during the read operation to generate the first to “N”^{th} data DATA<1:N>. The first to “N”^{th} data DATA<1:N> may be output to the controller 10 during the read operation. The first to “N”^{th} data DATA<1:N> may be input/output in series. The first to “N”^{th} internal data ID<1:N> may be generated in parallel. The number of bits of the first to “N”^{th} data DATA<1:N> and the first to “N”^{th} internal data ID<1:N> may be set to various numbers of bits according to embodiments. The number of bits “N” of the first to “N”^{th} data DATA<1:N> and the first to “N”^{th} internal data ID<1:N> may be set to a positive integer.

The memory circuit 260 may include a plurality of memory cells MC. The memory circuit 260 may store the first to “N”^{th} internal data ID<1:N> in the memory cell MC selected by the first to “M”^{th} internal addresses IADD<1:M> when the write command WT is enabled. The memory circuit 260 may output the first to “N”^{th} internal data ID<1:N> stored in the memory cell MC that is selected by the first to “M”^{th} internal addresses IADD<1:M> when the read command RD is enabled.

The electronic device 20 may control the current input and output between the power supply voltage (VDD in FIG. 3) terminal and ground voltage (VSS in FIG. 3) terminal and the internal nodes according to the voltages of the input signal IN and the inverted input signal INB. The electronic device 20 may sense and amplify the voltage difference between the input signal IN and the inverted input signal INB to generate the internal clock (ICLK in FIG. 2). The electronic device 20 may latch the data DATA serially input in synchronization with the internal clock (ICLK in FIG. 2) during the write operation, based on the command address CA. The electronic device 20 may align the latched data DATA to store the internal data (ID<1:N> in FIG. 2) generated in parallel during the write operation. The electronic device 20 may serialize the internal data (ID<1:N> in FIG. 2) stored therein in synchronization with the internal clock (ICLK in FIG. 2) during the read operation, based on the command address CA. The electronic device 20 may output the serialized internal data (ID<1:N> in FIG. 2) as the data DATA during the read operation.

The reception circuit 220 included in the electronic device 20 may generate the internal clock ICLK having a voltage between the power supply voltage VDD and the ground voltage VSS even when the voltages of the input signal IN and the inverted input signal INB input to an input unit (310 in FIGS. 3 and 350 in FIG. 4) having a rail-to-rail structure are low voltages. Therefore, the voltage ranges of the input signal IN and the inverted input signal INB can be maximized. The reception circuit 220 included in the electronic device 20 may reduce current consumption by applying a transfer gate (331_5 in FIG. 3, 371_5 in FIG. 4) included in a second current source (330 in FIG. 3, 370 in FIG. 4). The reception circuit 220 included in the electronic device 20 may be implemented to have a single-ended structure the reception circuit 220 senses and amplifies a voltage difference between two signals, the input signal IN and the inverted input signal INB, to generate one signal, the internal clock ICLK.

FIG. 3 is a circuit diagram illustrating a reception circuit 220a according to an embodiment of the reception circuit 220 included in the electronic device 20 shown in FIG. 2. The reception circuit 220a may include an input unit 310, a first current source 320, a second current source 330, and an output unit 340.

The input unit 310 may include an NMOS transistor 311_1 positioned between the ground voltage VSS and a supply node nd311, an NMOS transistor 311_2 positioned between the supply node nd311 and an internal node nd321, and an NMOS transistor 311_3 positioned between the supply node nd311 and an internal node nd331. The NMOS transistor 311_1 may receive the first control voltage VN through a gate, and be turned on to supply the ground voltage VSS to the supply node nd311. The NMOS transistor 311_2 may be turned on when the voltage of the input signal IN is a high voltage (a first voltage level) to increase a current that is output from the internal node nd321 to the supply node nd311. The current output from the internal node nd321 to the supply node nd311 may be set to a product of the amplification factor gm of the NMOS transistor 311_2 and the voltage of the input signal IN. The NMOS transistor 311_3 may be turned on when the voltage of the inverted input signal INB is a high voltage (the first voltage level) to increase a current that is output from the internal node nd331 to the supply node nd311. The current output from the internal node nd331 to the supply node nd311 may be set to a product of the amplification factor gm of the NMOS transistor 311_3 and the voltage of the inverted input signal INB. The amplification factor gm means the transconductance of the transistor, and the amplification factor gm means the ratio at which the amount of current in a drain is controlled according to the voltage input to a gate.

In addition, the input unit 310 may include a PMOS transistor 311_4 positioned between the power supply voltage VDD terminal and a supply node nd312, a PMOS transistor 311_5 positioned between the supply node nd312 and an internal node nd322, and a PMOS transistor 311_6 positioned between the supply node nd312 and an internal node nd333. The PMOS transistor 311_4 may receive the second control voltage VP through a gate and be turned on to supply the power supply voltage VDD to the supply node nd312. The PMOS transistor 311_5 may be turned on when the voltage of the input signal IN is a low voltage (second voltage level) to increase the current output from the supply node nd312 to the internal node nd322. The current output from the supply node nd312 to the internal node nd322 may be set to a product of the amplification factor gm of the PMOS transistor 311_5 and the voltage of the input signal IN. The PMOS transistor 311_6 may be turned on when the voltage of the inverted input signal INB is a low voltage (second voltage level) to increase the current output from the supply node nd312 to the internal node nd333. The current output from the supply node nd312 to the internal node nd333 may be set to a product of the amplification factor gm of the PMOS transistor 311_6 and the voltage of the inverted input signal INB.

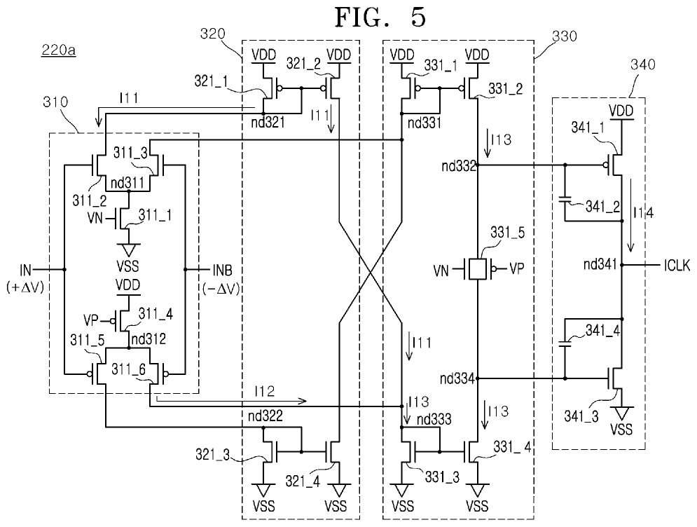

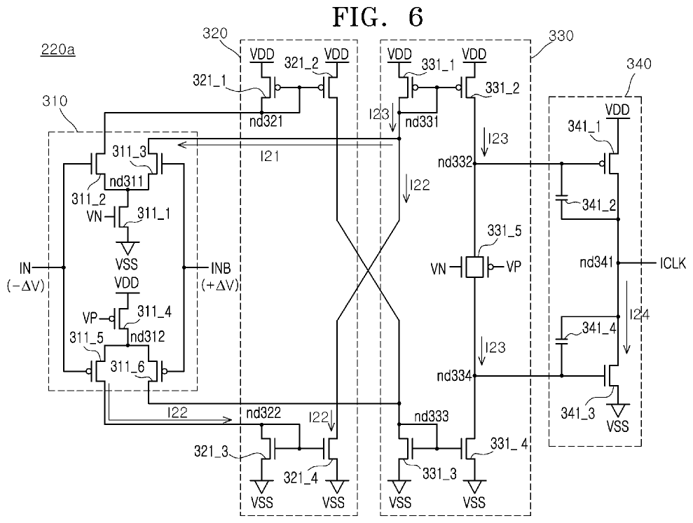

The input unit 310 may receive the ground voltage VSS by the first control voltage VN through the supply node nd311. The input unit 310 may receive the power supply voltage VDD by the second control voltage VP through the supply node nd312. The input unit 310 may control the current input and output between the power supply voltage VDD and ground voltage VSS terminals and the internal nodes nd321, nd331, nd322, and nd333 according to the voltages of the input signal IN and the inverted input signal INB. The operation of controlling the current input and output between the power supply voltage VDD and ground voltage VSS terminals and the internal nodes nd321, nd331, nd322, and nd333 according to the voltages of the input signal IN and the inverted input signal INB in the input unit 310 will be described in more detail with reference to FIGS. 5 and 6 to be described later.

The input unit 310 may be implemented to have a rail-to-rail structure. The rail-to-rail structure may mean a connection structure in which the input unit 310 can directly receive the power supply voltage VDD and the ground voltage VSS even when the voltage of the input signal is a low voltage to generate a signal having a voltage between the power supply voltage VDD and the ground voltage VSS.

The first current source 320 may include a PMOS transistor 321_1 positioned between the power supply voltage VDD terminal and the internal node nd321, and a PMOS transistor 321_2 positioned between the power supply voltage VDD terminal and the internal node nd333. A common gate of the PMOS transistor 321_1 and the PMOS transistor 321_2 may be connected to the internal node nd321. The PMOS transistor 321_1 may supply a current to the internal node nd321 from the power supply voltage VDD terminal. The PMOS transistor 321_2 may copy the current output from the internal node nd321 to the supply node nd311, and supply the same current to the internal node nd333.

In addition, the first current source 320 may include an NMOS transistor 321_3 positioned between the internal node nd322 and the ground voltage VSS terminal, and an NMOS transistor 321_4 positioned between the internal node nd331 and the ground voltage VSS. A common gate of the NMOS transistor 321_3 and the NMOS transistor 321_4 may be connected to the internal node nd322. The NMOS transistor 321_3 may output a current from the internal node nd322 to the ground voltage VSS terminal. The NMOS transistor 321_4 may copy the current output from the supply node nd312 to the internal node nd322, and output the same current to the ground voltage VSS terminal from the internal node nd331.

The second current source 330 may include a PMOS transistor 331_1 positioned between the power supply voltage VDD terminal and the internal node nd331, and a PMOS transistor 331_2 positioned between the power supply voltage VDD terminal and an internal node nd332. A common gate of the PMOS transistor 331_1 and the PMOS transistor 331_2 may be connected to the internal node nd331. The PMOS transistor 331_1 may supply a current obtained by copying the sum of the current output from the internal node nd331 to the supply node nd311 by the input unit 310 and the current output from the internal node nd331 to the ground voltage VSS terminal by the first current source 320 from the power supply voltage VDD terminal to the internal node nd331. The PMOS transistor 331_2 may copy the current supplied to the internal node nd331 by the PMOS transistor 331_1 to supply the same current from the power supply voltage VDD terminal to the internal node nd332.

In addition, the second current source 330 may include an NMOS transistor 331_3 positioned between the internal node nd333 and the ground voltage VSS terminal, and an NMOS transistor 331_4 positioned between an internal node nd334 and the ground voltage VSS. A common gate of the NMOS transistor 331_3 and the NMOS transistor 331_4 may be connected to the internal node nd333. The NMOS transistor 331_3 may supply a current obtained by copying the sum of the current supplied from the power supply voltage VDD terminal to the internal node nd333 by the input unit 310 and the current supplied from the power supply voltage VDD terminal to the internal node nd333 by the first current source 320 to the ground voltage VSS terminal. The NMOS transistor 331_4 may copy the current output to the ground voltage VSS terminal by the NMOS transistor 331_3 to output the same current to the ground voltage VSS terminal from the internal node nd334.

The second current source 330 may further include a transfer gate 331_5 that is positioned between the internal node nd332 and the internal node nd334 and turned on by the first control voltage VN and the second control voltage VP. The transfer gate 331_5 may control a voltage difference between the internal node nd332 and the internal node nd334. The transfer gate 331_5 may control the voltage difference between the internal node nd332 and the internal node nd334 by the current output from the PMOS transistor 331_2 to the ground voltage VSS terminal through the NMOS transistor 331_4. The transfer gate 331_5 may increase the voltage difference between the internal node nd332 and the internal node nd334 as the current output from the PMOS transistor 331_2 to the ground voltage VSS terminal through the NMOS transistor 331_4 increases. The transfer gate 331_5 may reduce the voltage difference between the internal node nd332 and the internal node nd334 as the current output from the PMOS transistor 331_2 to the ground voltage VSS terminal through the NMOS transistor 331_4 is reduced.

The output unit 340 may include a PMOS transistor 341_1 positioned between the power supply voltage VDD terminal and an output node nd341, and an NMOS transistor 341_3 positioned between the output node nd341 and the ground voltage VSS terminal. The PMOS transistor 341_1 may supply a current from the power supply voltage VDD terminal to the output node nd341 to generate the internal clock ICLK when the PMOS transistor 341_1 receives the voltage of the internal node nd332 through a gate and is turned on. The NMOS transistor 341_3 may output the current from the output node nd341 to the ground voltage VSS to generate the internal clock ICLK when the NMOS transistor 341_3 receives the voltage of the internal node nd334 through a gate and is turned on.

In addition, the output unit 340 may include a capacitor 341_2 positioned between the internal node nd332 and the output node nd341, and a capacitor 341_4 positioned between the internal node nd334 and the output node nd341. The capacitor 341_2 may prevent an oscillation operation in which the voltage of the output node nd341 rapidly changes due to the operations of the second current source 330 and the output unit 340, thereby stabilizing the frequency of the internal clock ICLK. The capacitor 341_4 may prevent the oscillation operation in which the voltage of the output node nd341 rapidly changes due to the operations of the second current source 330 and the output unit 340, thereby stabilizing the frequency of the internal clock ICLK.

FIG. 4 is a circuit diagram illustrating a configuration of a reception circuit 220b according to another embodiment of the reception circuit 220 included in the electronic device 20 shown in FIG. 2. As shown in FIG. 4, the reception circuit 220b may include an input unit 350, a first current source 360, a second current source 370, and an output unit 380.

The input unit 350 may include an NMOS transistor 351_1 positioned between the ground voltage VSS terminal and a supply node nd351, an NMOS transistor 351_2 positioned between the suplu node nd351 and an internal node nd361, and an NMOS transistor 351_3 positioned between the supply node nd351 and an internal node nd371. The NMOS transistor 351_1 may receive the first control voltage VN through a gate and be turned on to supply the ground voltage VSS terminal to the supply node nd351. The NMOS transistor 351_2 may be turned on when the voltage of the input signal IN is a high voltage to increase a current output from the internal node nd361 to the supply node nd351. The current output from the internal node nd361 to the supply node nd351 may be set to a product of the amplification factor gm of the NMOS transistor 351_2 and the voltage of the input signal IN. The NMOS transistor 351_3 may be turned on when the voltage of the inverted input signal INB is a high voltage to increase a current output from the internal node nd371 to the supply node nd351. The current output from the internal node nd371 to the supply node nd351 may be set to a product of the amplification factor gm of the NMOS transistor 351_3 and the voltage of the inverted input signal INB. The amplification factor gm may mean the transconductance of the transistor, and the amplification factor gm may mean the ratio at which the amount of a current in the drain is adjusted according to the voltage input to the gate.

In addition, the input unit 350 may include a PMOS transistor 351_4 positioned between the power supply voltage VDD terminal and a supply node nd352, a PMOS transistor 351_5 positioned between the supply node nd352 and an internal node nd362, and a PMOS transistor 351_6 positioned between the supply node nd352 and an internal node nd373. The PMOS transistor 351_4 may receive the second control voltage VP through a gate and be turned on to supply the power supply voltage VDD to the supply node nd352. The PMOS transistor 351_5 may be turned on when the voltage of the input signal IN is a low voltage to increase a current output from the supply node nd352 to the internal node nd362. The current output from the supply node nd352 to the internal node nd362 may be set to a product of the amplification factor gm of the PMOS transistor 351_5 and the voltage of the input signal IN. The PMOS transistor 351_6 may be turned on when the voltage of the inverted input signal INB is a low voltage to increase a current output from the supply node nd352 to the internal node nd373. The current output from the supply node nd352 to the internal node nd373 may be set to a product of the amplification factor gm of the PMOS transistor 351_6 and the voltage of the inverted input signal INB.

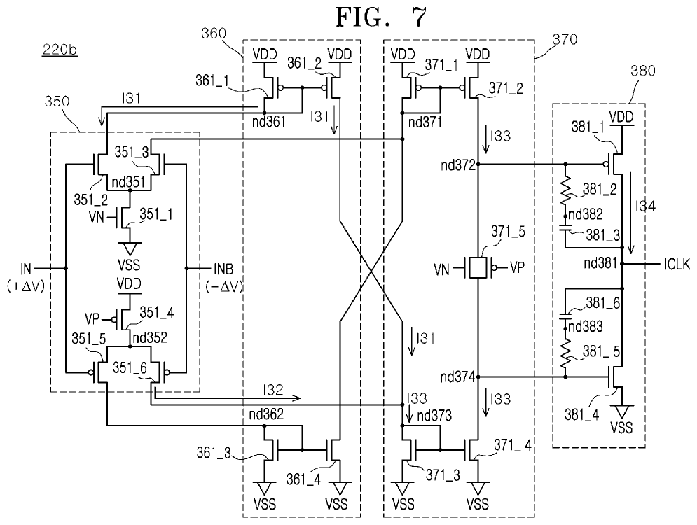

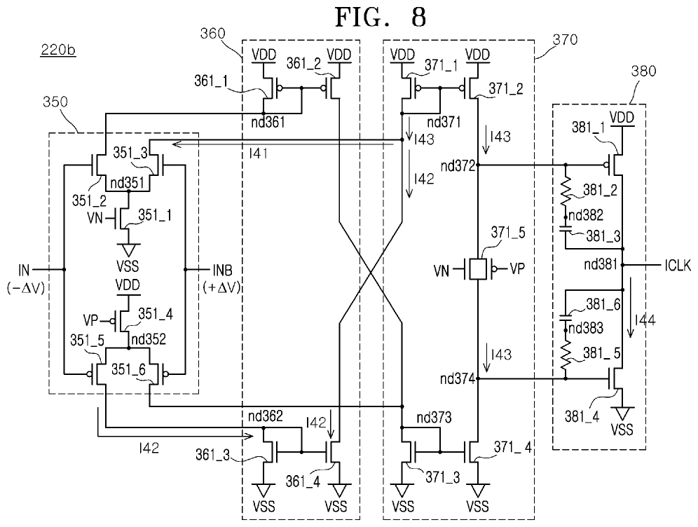

The input unit 350 may receive the ground voltage VSS by the first control voltage VN through the supply node nd351. The input unit 350 may receive the power supply voltage VDD by the second control voltage VP through the supply node nd352. The input unit 350 may control the current input and output between the power supply voltage VDD and ground voltage VSS terminals and the internal nodes nd361, nd371, nd362, and nd373 according to the voltages of the input signal IN and the inverted input signal INB. The operation of controlling the current input and output between the power supply voltage VDD and ground voltage VSS terminals and the internal nodes nd361, nd371, nd362, and nd373 according to the voltages of the input signal IN and the inverted input signal INB will be described in more detail with reference to FIGS. 7 and 8 to be described later.

The input unit 350 may be implemented to have the rail-to-rail structure. The rail-to-rail structure may mean a connection structure in which the input unit 350 may directly receive the power supply voltage VDD and the ground voltage VSS even when the voltage of the input signal is a low voltage to generate a signal having a voltage between the power supply voltage VDD and the ground voltage VSS.

The first current source 360 may include a PMOS transistor 361_1 positioned between the power supply voltage VDD terminal and an internal node nd361 and a PMOS transistor positioned between the power supply voltage VDD terminal and an internal node nd373. A common gate of the PMOS transistor 361_1 and the PMOS transistor 361_2 may be connected to the internal node nd361. The PMOS transistor 361_1 may supply a current from the power supply voltage VDD terminal to the internal node nd361. The PMOS transistor 361_2 may copy the current output from the internal node nd361 to the supply node nd351 to supply the same current to the internal node nd373.

In addition, the first current source 360 may include an NMOS transistor 361_3 positioned between the internal node nd362 and the ground voltage VSS terminal, and an NMOS transistor 361_4 positioned between the internal node 371 and the ground voltage VSS terminal. A common gate of the NMOS transistor 361_3 and the NMOS transistor 361_4 may be connected to the internal node nd362. The NMOS transistor 361_3 may output a current from the internal node nd362 to the ground voltage VSS terminal. The NMOS transistor 361_4 may copy the current output from the supply node nd352 to the internal node nd362 to output the same current from the internal node nd371 to the ground voltage VSS terminal.

The second current source 370 may include a PMOS transistor 371_1 positioned between the power supply voltage VDD terminal and the internal node nd371, and a PMOS transistor 371_2 positioned between the power supply voltage VDD terminal and the internal node nd372. A common gate of the PMOS transistor 371_1 and the PMOS transistor 371_2 may be connected to the internal node nd371. The PMOS transistor 371_1 may supply a current obtained by copying the sum of the current output from the internal node nd371 to the supply node nd351 by the input unit 350 and the current output from the internal node nd371 to the ground voltage VSS terminal by the first current source 360 to the internal node nd371. The PMOS transistor 371_2 may copy the current supplied to the internal node nd371 by the PMOS transistor 371_1 to supply the same current from the power supply voltage VDD terminal to the internal node nd372.

In addition, the second current source 370 may include an NMOS transistor 371_3 positioned between an internal node nd373 and the ground voltage VSS terminal, and an NMOS transistor 371_4 positioned between an internal node nd374 and the ground voltage VSS terminal. A common gate of the NMOS transistor 371_3 and the NMOS transistor 371_4 may be connected to the internal node nd373. The NMOS transistor 371_3 may output a current obtained by copying the sum of the current supplied from the power supply voltage VDD terminal to the internal node nd373 by the input unit 350 and the current supplied from the power supply voltage VDD terminal to the internal node nd373 by the first current source 360 to the ground voltage VSS terminal. The NMOS transistor 371_4 may copy the current output to the ground voltage VSS terminal by the NMOS transistor 371_3 to output the same current from the internal node nd374 to the ground voltage VSS terminal.

In addition, the second current source 370 may include a transfer gate 371_5 that is positioned between the internal node nd372 and the internal node nd374 and is turned on by the first control voltage VN and the second control voltage VP. The transfer gate 371_5 may control a voltage difference between the internal node nd372 and the internal node nd374. The transfer gate 371_5 may control the voltage difference between the internal node nd372 and the internal node nd374 by the current output from the PMOS transistor 371_2 to the ground voltage VSS terminal through the NMOS transistor 371_4. The transfer gate 371_5 may increase the voltage difference between the internal node nd372 and the internal node nd374 as the current output from the PMOS transistor 371_2 to the ground voltage VSS through the NMOS transistor 371_4 increases. The transfer gate 371_5 may reduce the voltage difference between the internal node nd372 and the internal node nd374 as the current output from the PMOS transistor 371_2 to the ground voltage VSS terminal through the NMOS transistor 371_4 is reduced.

The output unit 380 may include a PMOS transistor 381_1 positioned between the power supply voltage VDD terminal and an output node nd381, and an NMOS transistor 381_4 positioned between the output node nd381 and the ground voltage VSS terminal. When the PMOS transistor 381_1 receives the voltage of the internal node nd372 through a gate and is turned on, the PMOS transistor 381_1 may supply a current from the power supply voltage VDD terminal to the output node nd381 to generate the internal clock ICLK. When the NMOS transistor 381_4 receives the voltage of the internal node nd374 and is turned on, the NMOS transistor 381_4 may output a current from the output node nd381 to the ground voltage VSS terminal to generate the internal clock ICLK.

In addition, the output unit 380 may include a resistor 381_2 positioned between the internal node nd372 and an internal node nd382, a capacitor 381_3 positioned between the internal node nd382 and an output node nd381, a resistor 381_5 positioned between the internal node nd374 and an internal node nd383, and a capacitor 381_6 positioned between the internal node nd383 and the output node nd381. The resistor 381_2 and the capacitor 381_3 may prevent an oscillation operation in which the voltage of the output node nd381 rapidly changes due to the operation of the second current source 370 and the output unit 380, thereby stabilizing the frequency of the internal clock ICLK. The resistor 381_5 and the capacitor 381_6 may prevent the oscillation operation in which the voltage of the output node nd381 rapidly changes due to the operation of the second current source 370 and the output unit 380, thereby stabilizing the frequency of the internal clock ICLK.

FIGS. 5 and 6 are circuit diagrams illustrating operations of the reception circuit of the present disclosure. The operation of the reception circuit 220a according to an embodiment of the present disclosure will be described with reference to FIG. 5. The operation of generating the internal clock ICLK when the input signal IN has a high voltage (first voltage level=+Δ) and the inverted input signal INB has a low voltage (second voltage level=−Δ) will be described as follows.

The NMOS transistor 311_1 of the input unit 310 may receive the first control voltage VN through a gate and be turned on to supply the ground voltage VSS to the supply node nd311. The PMOS transistor 311_4 may receive the second control voltage VP through a gate and be turned on to supply the power supply voltage VDD to the supply node nd312.

The NMOS transistor 311_2 of the input unit 310 may be turned on when the voltage of the input signal IN is a high voltage (first voltage level) to increase a current I11 output from the internal node nd321 to the supply node nd311. The current I11 output from the internal node nd321 to the supply node nd311 may be set to a product of the amplification factor gm of the NMOS transistor 311_2 and the voltage of the input signal IN. The NMOS transistor 311_3 may be turned off when the voltage of the inverted input signal INB is a low voltage (second voltage level=−Δ).

The PMOS transistor 311_6 of the input unit 310 may be turned on when the voltage of the inverted input signal INB is a low voltage (second voltage level) to increase a current I12 output from the supply node nd312 to the internal node nd333. The current I12 output from the supply node nd312 to the internal node nd333 may be set to a product of the amplification factor gm of the PMOS transistor 311_6 and the voltage of the inverted input signal INB. The PMOS transistor 311_5 may be turned off when the voltage of the input signal IN is a high voltage (first voltage level).

The PMOS transistor 321_1 of the first current source 320 may supply a current from the power supply voltage VDD terminal to the internal node nd321. The PMOS transistor 321_2 of the first current source 320 may copy the current output from the internal node nd321 to the supply node nd311 to supply the same current I11 to the internal node nd333.

The NMOS transistor 331_3 of the second current source 330 may output a current I13 obtained by copying the sum of the current I12 supplied from the power supply voltage VDD terminal to the internal node nd333 by the input unit 310 and the current I11 supplied from the power supply voltage VDD terminal to the internal node nd333 by the first current source 320 to the ground voltage VSS terminal. The NMOS transistor 331_4 may copy the current I13 output to the ground voltage VSS terminal by the NMOS transistor 331_3 to output the same current I13 from the internal nd334 to the ground VSS terminal.

The transfer gate 331_5 of the second current source 330 may be turned on by the first control voltage VN and the second control voltage VP. Because the current I13 is output from the PMOS transistor 331_2 of the second current source 330 to the ground voltage VSS terminal through the NMOS transistor 331_4, the voltage at the internal node nd332 may be generated as a low voltage.

The PMOS transistor 341_1 of the output unit 340 may receive the voltage of the internal node nd332 through a gate and be turned on to supply a current I14 from the power supply voltage VDD terminal to the output node nd341 and to increase the internal clock ICLK to a high voltage. The capacitor 341_2 of the output unit 340 may prevent an oscillation operation in which the voltage of the output node nd341 rapidly changes due to the operations of the second current source 330 and the output unit 340, thereby stabilizing the frequency of the internal clock ICLK. When the internal clock ICLK is generated with a high voltage, it means that the internal clock ICLK is generated at the power supply voltage VDD level.

The above-described reception circuit 220a may generate the internal clock ICLK having a voltage between the power supply voltage VDD and the ground voltage VSS even when the voltages of the input signal IN and the inverted input signal INB that are input to the input unit 310 having a rail-to-rail structure are low voltages, thereby maximizing the voltage ranges of the input signal IN and the inverted input signal INB. The reception circuit 220a may reduce current consumption by applying the transfer gate 331_5 included in the second current source 330. The reception circuit 220a may be implemented in a single-ended structure in which the reception circuit 220a senses and amplifies the voltage difference between two signals, the input signal IN and the inverted input signal INB, to generate one signal, the internal clock ICLK.

The operation of the reception circuit 220a according to an embodiment of the present disclosure will be described with reference to FIG. 6. The operation of generating the internal clock ICLK when the input signal IN has a low voltage (second voltage level=−Δ) and the inverted input signal INB has a high voltage (first voltage level=+Δ) will be described as follows.

The NMOS transistor 311_1 of the input unit 310 may receive the first control voltage VN through a gate and be turned on to supply the ground voltage VSS to the supply node nd311. The PMOS transistor 311_4 of the input unit 310 may receive the second control voltage VP through a gate and be turned on to supply the power supply voltage VDD to the supply node nd312.

The NMOS transistor 311_3 of the input unit 310 may be turned when the voltage of the inverted input signal INB is a high voltage (first voltage level) to increase a current I21 output from the internal node nd331 to the supply node nd311. The current I21 output from the internal node nd331 to the supply node nd311 may be set to a product of the amplification factor gm of the NMOS transistor 311_3 and the voltage of the inverted input signal INB. The NMOS transistor 311_2 may be turned off when the voltage of the input signal IN is a low voltage (second voltage level).

The PMOS transistor 311_5 of the input unit 310 may be turned on when the voltage of the input signal IN is a low voltage (second voltage level) to increase a current I22 output from the supply node nd312 to the internal node nd322. The current I22 output from the supply node nd312 to the internal node nd322 may be set to a product of the amplification factor gm of the PMOS transistor 311_5 and the voltage of the input signal IN. The PMOS transistor 311_6 may be turned off when the voltage of the inverted input signal INB is a high voltage (first voltage level=+Δ).

The NMOS transistor 321_3 of the first current source 320 may output the current I22 from the internal node nd322 to the ground voltage VSS terminal. The NMOS transistor 321_4 of the first current source 320 may copy the current I22 output from the supply node nd312 to the internal node nd322 to output the same current I22 from the internal node nd331 to the ground voltage VSS terminal.

The PMOS transistor 331_1 of the second current source 330 may supply a current I23 obtained by copying the sum of the current I21 output from the internal node nd331 to the supply node nd311 by the input unit 310 and the current I22 output to the ground voltage VSS terminal from the internal node nd331 by the first current source 320 to the internal node nd331. The PMOS transistor 331_2 of the second current source 330 may copy the current I23 supplied to the internal node nd331 by the PMOS transistor 331_1 to supply the same current I23 from the power supply voltage VDD terminal to the internal node nd332.

The transfer gate 331_5 of the second current source 330 may be turned on by the first control voltage VN and the second control voltage VP. Because the current I23 is not output from the PMOS transistor 331_2 of the second current source 330 to the ground voltage VSS terminal through the NMOS transistor 331_4, the voltage of the internal node nd334 may be generated as a high voltage.

The NMOS transistor 341_3 of the output unit 340 may receive the voltage of the internal node nd334 through a gate to be turned on and output a current I24 to the ground voltage VSS terminal to decrease the voltage of the internal clock ICLK to a low voltage. The capacitor 341_4 of the output unit 340 may prevent an oscillation operation in which the voltage of the output node nd341 rapidly changes due to the operations of the second current source 330 and the output unit 340, thereby stabilizing the frequency of the internal clock ICLK. When the voltage of the internal clock ICLK is reduced to a low voltage and generated, it means that the internal clock ICLK is generated at the ground voltage VSS level.

The above-described reception circuit 220a may generate the internal clock ICLK having a voltage between the power supply voltage VDD and the ground voltage VSS even when the voltages of the input signal IN and the inverted input signal INB that are input to the input unit 310 having a rail-to-rail structure are low voltages, thereby maximizing the voltage ranges of the input signal IN and the inverted input signal INB. The reception circuit 220a may reduce current consumption by applying the transfer gate 331_5 included in the second current source 330. The reception circuit 220a may be implemented in a single-ended structure in which the reception circuit 220a senses and amplifies the voltage difference between two signals, the input signal IN and the inverted input signal INB, to generate one signal, the internal clock ICLK.

FIGS. 7 and 8 are circuit diagrams illustrating operations of the reception circuit of the present disclosure. The operation of the reception circuit 220b according to an embodiment of the present disclosure will be described with reference to FIG. 7. The operation of generating the internal clock ICLK when the input signal IN has a high voltage (first voltage level=+Δ) and the inverted input signal INB has a low voltage (second voltage level=−Δ) will be described as follows.

The NMOS transistor 351_1 of the input unit 350 may receive the first control voltage VN through a gate and be turned on to supply the ground voltage VSS to the supply node nd351. The PMOS transistor 351_4 of the input unit 350 may receive the second control voltage VP through a gate and be turned on to supply the power supply voltage VDD to the supply node nd352.

The NMOS transistor 351_2 of the input unit 350 may be turned on when the voltage of the input signal IN is a high voltage (first voltage level) to increase a current I31 output from the internal node nd361 to the supply node nd351. The current I31 output from the internal node nd361 to the supply node nd351 may be set to a product of the amplification factor gm of the NMOS transistor 351_2 and the voltage of the input signal IN. The NMOS transistor 351_3 may be turned off when the voltage of the inverted input signal INB is a low voltage (second voltage level=−Δ).

The PMOS transistor 351_6 of the input unit 350 may be turned on when the voltage of the inverted input signal INB is a low voltage (second voltage level) to increase a current I32 output from the supply node nd352 to the internal node nd373. The current I32 output from the supply node nd352 to the internal node nd373 may be set to a product of the amplification factor gm of the PMOS transistor 351_6 and the voltage of the inverted input signal INB. The PMOS transistor 351_5 may be turned off when the voltage of the input signal IN is a high voltage (first voltage level).

The PMOS transistor 361_1 of the first current source 360 may supply a current from the power supply voltage VDD terminal to the internal node nd361. The PMOS transistor 361_2 of the first current source 360 may copy the current I31 supplied from the internal node nd361 to the supply node nd351 to supply the same current I31 to the internal node nd373.

The NMOS transistor 371_3 of the second current source 370 may output a current I33 obtained by copying the sum of the current I32 supplied from the power supply voltage VDD terminal to the internal node nd373 by the input unit 350 and the current I31 supplied from the power supply voltage VDD terminal to the internal node nd373 by the first current source 360 to the ground voltage VSS terminal. The NMOS transistor 371_4 may copy a current I33 output from the ground voltage VSS terminal by the NMOS transistor 371_3 to output the same current I33 from the internal node nd374 to the ground voltage VSS terminal.

The transfer gate 371_5 of the second current source 370 may be turned on by the first control voltage VN and the second control voltage VP. Because the current I33 is output from the PMOS transistor 371_2 of the second current source 370 to the ground voltage VSS terminal through the NMOS transistor 371_4, the voltage of the internal node nd372 may be generated as a low voltage.

The PMOS transistor 381_1 of the output unit 380 may receive the voltage of the internal node nd372 through a gate to be turned on and supply a current I34 from the power supply voltage VDD terminal to the output node nd381 to increase the voltage of the internal clock ICLK to a high voltage. The resistor 381_2 and the capacitor 381_3 of the output unit 380 may prevent an oscillation operation in which the voltage of the output node nd381 rapidly changes due to the operations of the second current source 370 and the output unit 380, thereby stabilizing the frequency of the internal clock ICLK. When the internal clock ICLK is generated with a high voltage, it means that the internal clock ICLK is generated at the power supply voltage VDD level.

The above-described reception circuit 220b may generate the internal clock ICLK having a voltage between the power supply voltage VDD and the ground voltage VSS even when the voltages of the input signal IN and the inverted input signal INB that are input to the input unit 350 having a rail-to-rail structure are low voltages, thereby maximizing the voltage ranges of the input signal IN and the inverted input signal INB. The reception circuit 220b may reduce current consumption by applying the transfer gate 371_5 included in the second current source 370. The reception circuit 220b may be implemented in a single-ended structure in which the reception circuit 220b senses and amplifies the voltage difference between two signals, the input signal IN and the inverted input signal INB, to generate one signal, the internal clock ICLK.

The operation of the reception circuit 220b according to an embodiment of the present disclosure will be described with reference to FIG. 8. The operation of generating the internal clock ICLK when the input signal IN has a low voltage (second voltage level=−Δ) and the inverted input signal INB has a high voltage (first voltage level=+Δ) will be described as follows.

The NMOS transistor 351_1 of the input unit 350 may receive the first control voltage VN through a gate and be turned on to supply the ground voltage VSS to the supply node nd351. The PMOS transistor 351_4 of the input unit 350 may receive the second control voltage VP through a gate and be turned on to supply the power supply voltage VDD to the supply ode nd352.

The NMOS transistor 351_3 of the input unit 350 may be turned on when the voltage of the inverted input signal INB is a high voltage to increase a current I41 output from the internal node nd371 to the supply node nd351. The current I41 output from the internal node nd371 to the supply node nd351 may be set to a product of the amplification factor gm of the NMOS transistor 351_3 and the voltage of the inverted input signal INB. The NMOS transistor 351_2 may be turned off when the voltage of the input signal IN is a low voltage (second voltage level).

The PMOS transistor 351_5 of the input unit 350 may be turned on when the voltage of the input signal IN is a low voltage (second voltage level) to increase a current I42 output from the supply node nd352 to the internal node nd362. The current I42 output from the supply node nd352 to the internal node nd362 may be set to a product of the amplification factor gm of the PMOS transistor 351_5 and the voltage of the input signal IN. The PMOS transistor 351_6 may be turned off when the voltage of the inverted input signal INB is a high voltage (first voltage level=+Δ).

The NMOS transistor 361_3 of the first current source 360 may output the current I42 from the internal node nd362 to the ground voltage VSS terminal. The NMOS transistor 361_4 of the first current source 360 may copy the current I42 output from the supply node nd352 to the internal node nd362 to output the same current I42 from the internal node nd371 to the ground voltage VSS terminal.

The PMOS transistor 371_1 of the second current source 370 may supply a current obtained by copying the sum of the current I41 output from the internal node nd371 to the supply node nd351 by the input unit 350 and the current I42 output from the internal node nd371 to the ground voltage VSS terminal by the first current source 360 to the internal node nd371. The PMOS transistor 371_2 of the second current source 370 may copy the current I43 supplied to the internal node nd371 by the PMOS transistor 371_1 to supply the same current I43 from the power supply voltage VDD terminal to the internal node nd372.

The transfer gate 371_5 of the second current source 370 may be turned on by the first control voltage VN and the second control voltage VP. Because the current I43 is not output to the ground voltage VSS terminal from the PMOS transistor 371_2 of the second current source 370 through the NMOS transistor 371_4, the voltage at the internal node nd374 may be generated as a high voltage.

The NMOS transistor 381_4 of the output unit 380 may receive the voltage of the internal node nd374 to be turned on, and output a current I44 from the output node nd381 to the ground voltage VSS terminal to reduce the voltage of the internal clock ICLK to a low voltage. The resistor 381_5 and the capacitor 381_6 of the output unit 380 may prevent an oscillation operation in which the voltage of the output node nd381 rapidly changes due to the operations of the second current source 370 and the output unit 380, thereby stabilizing the frequency of the internal clock ICLK. When the voltage of the internal clock ICLK is reduced to a low voltage and generated, it means that the internal clock ICLK is generated at the ground voltage VSS level.

The above-described reception circuit 220b may generate the internal clock ICLK having a voltage between the power supply voltage VDD and the ground voltage VSS even when the voltages of the input signal IN and the inverted input signal INB that are input to the input unit 350 having a rail-to-rail structure are low voltages, thereby maximizing the voltage ranges of the input signal IN and the inverted input signal INB. The reception circuit 220b may reduce current consumption by applying the transfer gate 371_5 included in the second current source 370. The reception circuit 220b may be implemented in a single-ended structure in which the reception circuit 220b senses and amplifies the voltage difference between two signals, the input signal IN and the inverted input signal INB, to generate one signal, the internal clock ICLK.

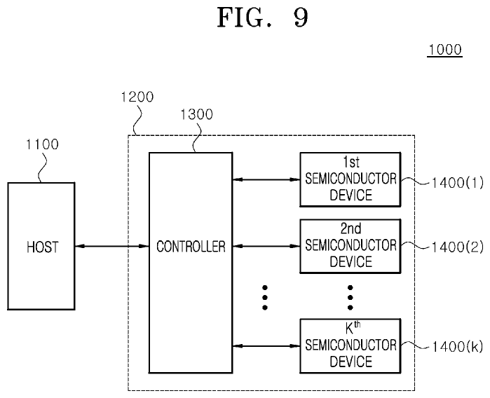

FIG. 9 is a block diagram illustrating a configuration of an electronic system 1000 according to an embodiment of the present disclosure. As shown in FIG. 9, the electronic system 1000 may include a host 1100 and a semiconductor system 1200.

The host 1100 and the semiconductor system 1200 may transmit signals to each other using interface protocols. The interface protocols used between the host 1100 and the semiconductor system 1200 may include a multi-media card (MMC), an enhanced small disk interface (ESDI), integrated drive electronics (IDE), peripheral component interconnect-express (PCI-E), advanced technology attachment (ATA), serial ATA (SATA), parallel ATA (PATA), serial attached SCSI (SAS), universal serial bus (USB), and the like.

The semiconductor system 1200 may include a controller 1300 and semiconductor devices 1400 (1:K). The controller 1300 may control the semiconductor devices 1400 (1:K) to perform a write operation and a read operation. Each of the semiconductor devices 1400 (1:K) may generate an internal clock ICLK having a voltage between a power supply voltage VDD and a ground voltage VSS even when the voltages of the input signal IN and the inverted input signal INB that are input to an input unit having a rail-to-rail structure are low voltages, thereby maximizing the voltage ranges of an input signal IN and an inverted input signal INB. Each of the semiconductor devices 1400 (K:1) may reduce current consumption by applying a transfer gate included in a current source of a reception circuit included therein. Each of the semiconductor devices 1400 (K:1) may generate an internal clock having a stable frequency through a capacitor connected to an output node of the reception circuit included therein. Each of the semiconductor devices 1400 (K:1) may be implemented to have a single-ended structure in which each of the semiconductor devices 1400 (K:1) senses and amplifies a voltage difference between two signals, the input signal IN and the inverted input signal INB, to generate one signal, the internal clock ICLK.

The controller 1300 may be implemented as the controller 10 shown in FIG. 1. Each of the semiconductor devices 1400 (K:1) may be implemented as the semiconductor device 20 shown in FIG. 2. According to embodiments, each of the semiconductor devices 1400 (1:K) may be implemented with one of a dynamic random-access memory (DRAM) device, a phase change random-access memory (PRAM) device, a resistive random-access memory (RRAM) device, a magnetic random-access memory (MRAM) device, and ferroelectric random-access memory (FRAM) device.

Concepts have been disclosed in conjunction with some embodiments as described above. Those skilled in the art will appreciate that various modifications, additions, and/or substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. An electronic device comprising:
a reception circuit; and
a capacitor connected to an output node of the reception circuit,
wherein the reception circuit includes:
an input unit configured to receive an input signal and an inverted input signal;
a current source including a first PMOS transistor positioned between a power supply voltage terminal and a first internal node and a first NMOS transistor positioned between a ground voltage terminal and a second internal node, the current source configured to amplify a voltage difference of the input signal and the inverted input signal; and
an output unit configured to drive the output node according to a current supplied from the current source.

2. The electronic device of claim 1, wherein the input unit includes:
a second NMOS transistor positioned between the ground voltage terminal and a first supply node, the second NMOS transistor configured to be turned on by a first control voltage to directly supply a ground voltage to the first supply node; and
a second PMOS transistor positioned between the power supply voltage terminal and a second supply node, the second PMOS transistor configured to be turned on by a second control voltage to directly supply a power supply voltage to the second supply node.

3. The electronic device of claim 1, wherein the input unit is configured to:
receive the ground voltage and the power supply voltage directly, and
control a current input and output between the ground voltage and power supply voltage terminals and the first and second internal nodes according to voltages of the input signal and the inverted input signal.

4. The electronic device of claim 1,
wherein the current source includes a first current source,
wherein the first current source includes the first PMOS transistor and the first NMOS transistor, and
wherein the first current source is configured to supply a current to the first internal node through the first PMOS transistor, and to discharge a current of the second internal node through the first NMOS transistor.

5. The electronic device of claim 4,
wherein the current source further includes a second current source,
wherein the second current source includes third and fourth PMOS transistors and third and fourth NMOS transistors,
wherein the second current source is configured to supply a current to a third internal node through the third PMOS transistor, and to supply a current to a fifth internal node through the fourth PMOS transistor, and
wherein the second current source is configured to discharge a current of the fourth internal node through the third NMOS transistor, and to discharge a current of a sixth internal node through the fourth NMOS transistor.

6. The electronic device of claim 5,
wherein the second current source further includes a transfer gate, and
wherein the transfer gate is turned on by a first control voltage and a second control voltage to control a voltage difference of the fifth internal node and the sixth internal node.

7. The electronic device of claim 1, wherein the output unit includes:
a fifth PMOS transistor connected between the power supply voltage terminal and the output node, the fifth PMOS transistor configured to drive the output node by a voltage of the fifth internal node; and
a fifth NMOS transistor connected between the output node and the ground voltage terminal, the fifth NMOS transistor configured to drive the output node by a voltage of the sixth internal node.

8. The electronic device of claim 1, wherein the output unit includes:
a first capacitor connected between the fifth internal node and the output node; and
a second capacitor connected between the sixth internal node and the output node.

9. The electronic device of claim 1, wherein the output unit includes:
a first resistor connected between the fifth internal node and a seventh internal node;
a first capacitor connected between the seventh internal node and the output node;
a second resistor connected between the sixth internal node and an eighth internal node; and
a second capacitor connected between the eighth internal node and the output node.

10. The electronic device of claim 1, wherein the reception circuit is configured to drive the output node according to voltages of the input signal and the inverted input signal to generate an internal clock.

11. The electronic device of claim 10, wherein the reception circuit is configured to generate the internal clock when the voltages of the input signal and the inverted input signal are voltages between the power supply voltage and the ground voltage.

12. The electronic device of claim 10, wherein the reception circuit is configured to stabilize a frequency of the internal clock through the capacitor connected to the output node.

13. The electronic device of claim 1, wherein the reception circuit includes:
an input unit configured to directly receive a power supply voltage and a ground voltage by a first control voltage and a second control voltage, to output a first current from the first internal node to the ground voltage terminal when the input signal is at a first voltage level, and to supply a second current from the power supply voltage terminal to a fourth internal node when the inverted input signal is at a second voltage level;
a first current source configured to supply the first current to the fourth internal node;
a second current source configured to supply a third current, which is a sum of the first current and the second current, to a fifth internal node and a sixth internal node; and
an output unit configured to supply a current to the output node according to the third current supplied to the fifth internal node and the sixth internal node to generate an internal clock.

14. The electronic device of claim 1, wherein the reception circuit includes:
an input unit configured to directly receive a power supply voltage and a ground voltage by a first control voltage and a second control voltage, to output a first current from a third internal node to the ground voltage terminal when the inverted input signal is at a first voltage level, and to supply a second current from the power supply voltage terminal to the second internal node when the input signal is at a second voltage level;
a first current source configured to output the second current from the third internal node to the ground voltage terminal;
a second current source configured to supply a third current, which is a sum of the first current and the second current, to a fifth internal node and a sixth internal node; and
an output unit configured to supply a current to the output node according to the third current supplied to the fifth internal node and the sixth internal node to generate an internal clock.

15. An electronic device comprising:
a transmission circuit configured to output an input signal and an inverted input signal that have different voltages from each other; and
a reception circuit configured to connect a first supply node to a power supply voltage terminal through a first PMOS transistor that is turned on by a first control voltage, and to connect a second supply node to a ground voltage terminal through a first NMOS transistor that is turned on by a second control voltage,
wherein the reception circuit is configured to directly receive a power supply voltage through the first supply node, to directly receive a ground voltage through the second supply node, to control a current input and output between the power supply voltage and ground voltage terminals and internal nodes according to voltages of the input signal and the inverted input signal, and to sense and amplify a voltage difference between the input signal and the inverted input signal to generate an internal clock.

16. The electronic device of claim 15, wherein the reception circuit comprises a rail-to-rail structure in which the reception circuit directly receives the power supply voltage and the ground voltage through the first PMOS transistor and the first NMOS transistor.

17. The electronic device of claim 15, wherein the reception circuit comprises a single-ended structure in which the reception circuit senses and amplifies the voltage difference between the input signal and the inverted input signal to generate the internal clock.

18. The electronic device of claim 15, wherein the reception circuit is configured to stabilize a frequency of the internal clock through a first capacitor and a second capacitor connected to an output node where the internal clock is generated.

19. The electronic device of claim 15, wherein the reception circuit includes:
an input unit configured to directly receive the power supply voltage and the ground voltage by the first control voltage and the second control voltage, and to control a current input and output between the power supply voltage and ground voltage terminals and first to fourth internal nodes according to the voltages of the input signal and the inverted input signal;
a first current source configured to supply a current to the first and second internal nodes;
a second current source configured to supply a current to the third and fourth internal nodes and to supply a current to fifth and sixth internal nodes according to the current supplied to the third and fourth internal nodes; and
an output unit configured to supply or output a current to an output node according to the current supplied to the fifth and sixth internal nodes to generate the internal clock.

20. The electronic device of claim 19, wherein the output unit includes:
a first capacitor connected between the fifth internal node and the output node; and
a second capacitor connected between the sixth internal node and the output node, and
wherein a frequency of the internal clock is stabilized through the first capacitor and the second capacitor.

21. The electronic device of claim 19, wherein the output unit includes:
a first resistor connected between the fifth internal node and a seventh internal node;
a first capacitor connected between the seventh internal node and the output node;
a second resistor connected between the sixth internal node and an eighth internal node; and
a second capacitor connected between the eighth internal node and the output node, and
wherein a frequency of the internal clock is stabilized through the first capacitor and the second capacitor.

22. The electronic device of claim 15, wherein the reception circuit includes:
an input unit configured to directly receive the power supply voltage and the ground voltage by the first control voltage and the second control voltage, to output a first current from a first internal node to the ground voltage terminal when the input signal is at a first voltage level, and to supply a second current from the power supply voltage terminal to a fourth internal node when the inverted input signal is at a second voltage level;
a first current source configured to supply the first current to the fourth internal node;
a second current source configured to supply a third current, which is a sum of the first current and the second current, to fifth and sixth internal nodes; and
an output unit configured to supply a current to the output node according to the third current supplied to the fifth and sixth internal nodes to generate the internal clock.

23. The electronic device of claim 15, wherein the reception circuit includes:
an input unit configured to directly receive the power supply voltage and the ground voltage by the first control voltage and the second control voltage, to output a first current from a third internal node to the ground voltage terminal when the inverted input signal is at a first voltage level, and to supply a second current from the power supply voltage terminal to the second internal node when the input signal is at a second voltage level;
a first current source configured to output the second current from the third internal node to the ground voltage terminal;
a second current source configured to supply a third current, which is a sum of the first current and the second current, to fifth and sixth internal nodes; and
an output unit configured to supply a current to the output node according to the current supplied to the fifth and sixth internal nodes to generate the internal clock.
